(19) United States
(12) Patent Application Publication
(10) Pub. No.: US 2012/0098604 A1
(43) Pub. Date: Apr. 26, 2012

(54) RING OSCILLATOR AND CONTROL METHOD OF RING OSCILLATOR

(76) Inventor: Guo-hau Lee, Taipei City (TW)

(21) Appl. No.: 12/910,857

(22) Filed: Oct. 24, 2010

(51) Int. Cl. H03K 3/03

(52) U.S. Cl. 331/57

(57) ABSTRACT

A ring oscillator including a core circuit and a first adjusting circuit. The core circuit is for outputting a clock signal, and includes a plurality of ring stages. The first adjusting circuit is for receiving a plurality of first control information, and referring to the plurality of first control information to adjust the clock signal. The first adjusting circuit includes a plurality of bias circuits and a plurality of switch elements. The bias circuits are for providing a plurality of currents, and the switches are connected to the bias circuits in series and receive the plurality of first control information, respectively, wherein each switch element is selectively conducting according to a corresponding first control information for determining whether a current provided by a corresponding bias circuit is utilized to bias the core circuit.

### BACKGROUND OF THE INVENTION

1. Field of the Invention

The present invention relates to a clock generating circuit, and more particularly, to a ring oscillator.

2. Description of the Prior Art

Oscillators are generally used in electronic systems to provide stable clock signals. Among various architectures of oscillators, ring oscillator is often utilized in many system chips due to its simple structure and easy implementation.

However, a ring oscillator is generally constructed by multiple ring stages connected in a ring, where each ring stage is an inverse amplifier and an input signal at the input node of the inverse amplifier will be amplified at the output node of the inverse amplifier after a certain delay time, thereby generating an output signal of the ring stage. After traveling through a positive feedback loop consisting of all the ring stages, the input signal will vary its voltage level continuously and thereby turn out to be an oscillating signal. For example, please refer to FIG. 1 and FIG. 2 simultaneously, where FIG. 1 is a diagram of a conventional single-ended ring oscillator 100, and FIG. 2 illustrates partial signals within the single-ended ring oscillator 100 in FIG. 1. The ring oscillator 100 includes three ring stages 110, 120 and 130, and each ring stage is a single ended inverse amplifier, given the input signals of the ring stages 110, 120 and 130 are V_{SE1}, V_{SE2} and V_{SE3}, respectively, and a delay time provided by each ring stage is D_{SE}; since the ring stages 110, 120 and 130 are connected to each other as a ring, the output signals of the ring stages 110, 120 and 130 will be V_{SE2}, V_{SE3} and V_{SE1}, respectively. It can be seen from FIG. 2 that for each ring stage, an output signal is a result of inverting the input signal thereof after the delay time D_{S}E; on the other hand, each input signal, after being delayed by the ring stages 110, 120 and 130 successively, will travel back to its original starting point and present an inverse phase. As a result, each of the signals V_{SE1}, V_{SE2}, and V_{SE3} is an oscillating signal having a period of 6*D_{SE}, and changes its phase every 3*D_{SE}.

Generally speaking, when a ring oscillator is composed of single-ended inverse amplifiers, the number of employed ring stages must be an odd number to ensure that each signal is phase-inversed after being fed back to its original starting point; however, regarding a ring oscillator composed of differential amplifiers, this limitation does not exist. Please refer to FIG. 3, which is a diagram of a conventional differential ring oscillator 300. The differential ring oscillator 300 includes four ring stages 310, 320, 330 and 340, and each ring stage is a differential amplifier, and every ring stage is inversely connected to the next ring stage (i.e., each ring stage serves as an differential inverse amplifier) except for the connection between the ring stages 310 and 340. The ring stage 340 serves as a differential positive amplifier (its output signal and its input signal are of identical phase) when connected to the ring stage 310, therefore, although the number of the ring stages of the differential ring oscillator 300 is an even number, each signal will present an inverse phase when traveling back to its original starting point.

However, the commercial market has a great demand for high speed circuits, especially for high frequency phase locked loops (PLLs) in which an oscillator should not only be able to provide a low noise clock signal, but fulfill different design requirements such as high linearity and wideband frequency coverage. For an oscillator, linearity, operational bandwidth, phase noise and gain (i.e., Kvco) will have great influence on the overall performance, however, the aforementioned parameters usually interfere with each other, therefore during the design process, a balance point should be compromised in consideration of all parameters according to different requirements. For example, since a control signal for control an output frequency is usually limited by supply voltage, the operational bandwidth is substantially proportional to the gain (the operational bandwidth equals to a product of control signal variation range and the gain), when the gain declines, the operational bandwidth of the oscillator is also decreased, nevertheless, if the gain is enhanced to expand operational bandwidth, the enhanced gain will also enlarge the internal noise within the oscillator and result in a noisy output signal, and the phase noise is thereby deteriorated, a stability of the oscillator is also decreased. In addition, when the gain is enhanced to provide excessive operational bandwidth, the linearity of the gain is also impaired; leading to a degradation of system performance such as oscillator linearity, noise.

### SUMMARY OF THE INVENTION

In light of this, the exemplary embodiment of the present invention provides a multi-band ring oscillator with high linearity, which not only utilizes selectable bias currents to control oscillating frequency non-continuously so as to extend a larger adjustable frequency range of the oscillator, but also exploits controllable variable capacitors, which are constructed with transistors, between ring stages for continuously adjust oscillating frequency range, resulting a smaller gain (Kvco) of the oscillator, wherein one of the ring stages is composed of at least one single ended inverse amplifier or at least one differential inverse amplifier, or is composed of at least one single-ended inverse amplifier and at least one differential inverse amplifier.

According to an embodiment of the present invention, a ring oscillator including a core circuit, a first adjusting circuit and a second adjusting circuit is provided. The core circuit outputs a clock signal, and includes a plurality of ring stages, wherein each ring stage comprises an output node and an input node, the output node of the ring stage is coupled to an input node of a next ring stage, and the input node of the ring stage is coupled to an output node of a previous ring stage. The first adjusting circuit receives a plurality of first control information and refers to the plurality of first control information to adjust the clock signal generated by the core circuit non-continuously. The first adjusting circuit includes a plurality of bias circuits and a plurality of switch elements. The bias circuits provide a plurality of currents, respectively. The switch elements are coupled to the bias circuits in series and receive the plurality of first control information, respectively, wherein each switch element is selectively conducting according to corresponding first control information for determining whether a current provided by a corresponding bias circuit is utilized to bias the core circuit. The second adjusting circuit is coupled to the core circuit for receiving a second control information and adjusting the frequency of the clock signal according to the second control information. The second adjusting circuit includes at least one adjusting element, couple between an input node of a first ring stage and an output node of a second ring stage, wherein the first ring stage and the second ring stage are neighboring to each other within the ring stages, the adjusting element comprises at least one variable capacitor, and the variable capacitor is a transistor having two terminals thereof connected to each other.

According to another embodiment of the present invention, a ring oscillator including a core circuit, a first adjusting circuit and a second adjusting circuit is provided. The core circuit outputs a clock signal, and includes a plurality of ring stages, wherein each ring stage comprises an output node and an input node, the output node of the ring stage is coupled to an input node of a next ring stage, and the input node of the ring stage is coupled to an output node of a previous ring stage. The first adjusting circuit receives a plurality of first control information and refers to the plurality of first control information to adjust a gain of each ring stage within the core circuit non-continuously. The first adjusting circuit includes a plurality of bias circuits and a plurality of switch elements. The bias circuits provide a plurality of currents, respectively. The switch elements are coupled to the bias circuits in series and receive the plurality of first control information, respectively, wherein each switch element is selectively conducting according to corresponding first control information for determining whether a current provided by a corresponding bias circuit is utilized to bias the core circuit. The second adjusting circuit is coupled to the core circuit for receiving a second control information and adjusting a loading of each ring stage within the core circuit according to the second control information. The second adjusting circuit includes at least one adjusting element, couple between an input node of a first ring stage and an output node of a second ring stage, wherein the first ring stage and the second ring stage are neighboring to each other within the ring stages, the adjusting element comprises at least one variable capacitor, and the variable capacitor is a transistor having two terminals thereof connected to each other.

According to yet another embodiment of the present invention, a control method of a ring oscillator is provided. The control method includes: utilizing at least one switch element to control a bias current of the ring oscillator according to a first control information to non-continuously adjust a frequency of a clock signal of the ring oscillator; and utilizing a variable capacitor coupled to at least one ring stage within the ring oscillator to adjust a loading of the at lease one ring stage to continuously adjust the frequency of the clock signal.

The present invention provides a ring oscillator with high linearity and adjustable frequency. Via controlling a bias current of the ring oscillator, the goal of controlling a frequency of an output signal non-continuously can be achieved. In addition, the present invention simultaneously utilizes a voltage controlled variable capacitor (e.g., a MOS capacitor) coupled to each ring stage to adjust a loading of each ring stage continuously. In this way, the frequency of the output signal can be further fine-tuned. Besides, with a proper design, the ring oscillator of the present invention can have a wide adjustable frequency range while preserving great linearity.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a conventional single-ended ring oscillator.

FIG. 2 illustrates partial signals within the single-ended ring oscillator in FIG. 1.

FIG. 3 is a diagram of a conventional differential ring oscillator.

FIG. 4 is a diagram of a ring oscillator according to a first embodiment of the present invention.

FIG. 5A is a diagram of a first adjusting circuit according to an embodiment of the present invention.

FIG. 5B is a diagram showing a relation between a control voltage and an output frequency of the ring oscillator in FIG. 4 under different first control information.

FIG. 5C is a diagram of the first adjusting circuit according to an embodiment of the present invention.

FIG. 6 is a structural diagram of the first adjusting circuit according to an embodiment of the present invention.

FIG. 7 is a diagram of a first adjusting circuit according to another embodiment of the present invention.

FIG. 8 is a diagram of a ring oscillator according to a second embodiment of the present invention.

FIG. 9 is a diagram of an adjusting element according to an embodiment of the present invention.

FIG. 10 is a diagram showing the relation between the voltage across a variable capacitor and the equivalent capacitance of the variable capacitor when the transistor in FIG. 9 is utilized as the variable capacitor.

FIG. 11 is a diagram showing the relation between the second control information and the output frequency of the ring oscillator in FIG. 8 under different first control information.

FIG. 12 is a diagram of an adjusting element according another embodiment of the present invention.

FIG. 13 is a diagram of a ring oscillator according to a third embodiment of the present invention.

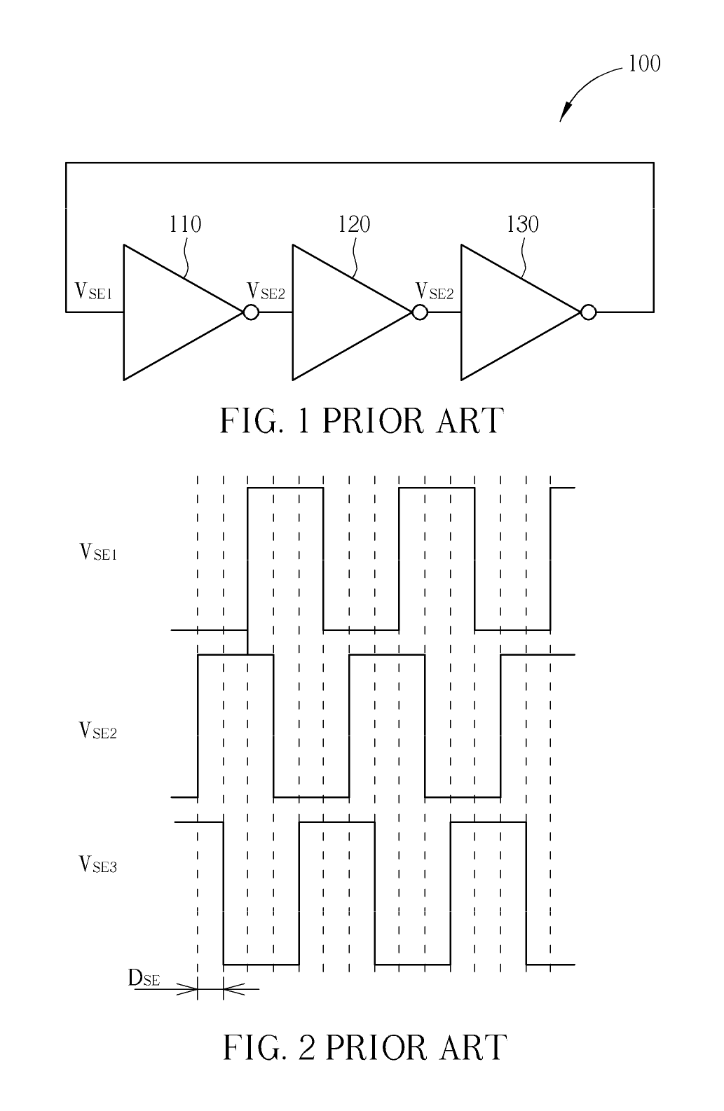

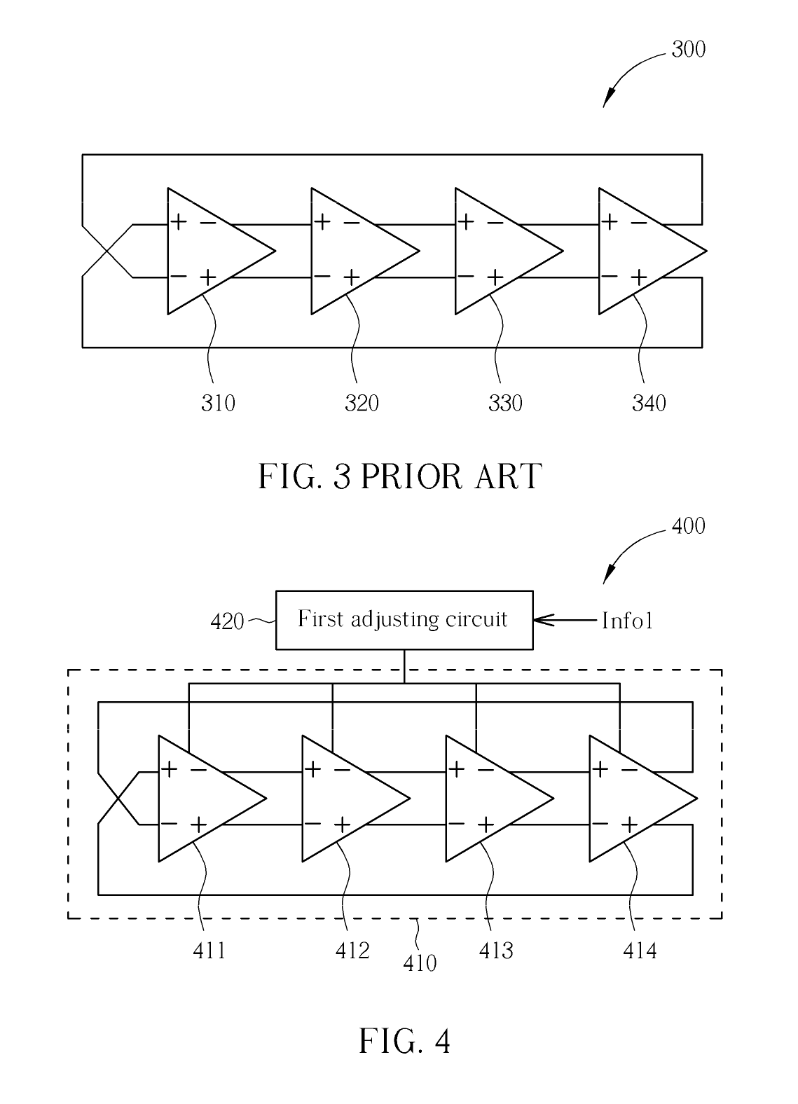

### DETAILED DESCRIPTION

Please refer to FIG. 4, which is a diagram of a ring oscillator 400 according to a first embodiment of the present invention. In this embodiment, the ring oscillator 400 includes (but not limited to) a core circuit 410 for outputting a clock signal and a first adjusting circuit 420. In addition, the core circuit 410 includes four differential ring stages 411, 412, 413 and 414; however, the aforementioned structure of the ring oscillator 400 is for illustrative purpose only. In other embodiments, the ring oscillator 400 may also be implemented by single-ended ring stages, and the number of the ring stages is not limited as well. As shown in the figure, in the core circuit 410, each ring stage includes an output terminal (−,+) and an input terminal (+,−), where the output terminal (−,+) is coupled to the input terminal (+,−) of a next ring stage, and the input terminal (+,−) is coupled a previous output terminal (−,+). The first adjusting circuit 420 is for receiving a plurality of first control information Info1, and adjusting the clock signal generated by the core circuit 410 according to the first control information Info1. In this embodiment, the first control information Info1 is a set of binary bits for controlling an operation of the core circuit 410.

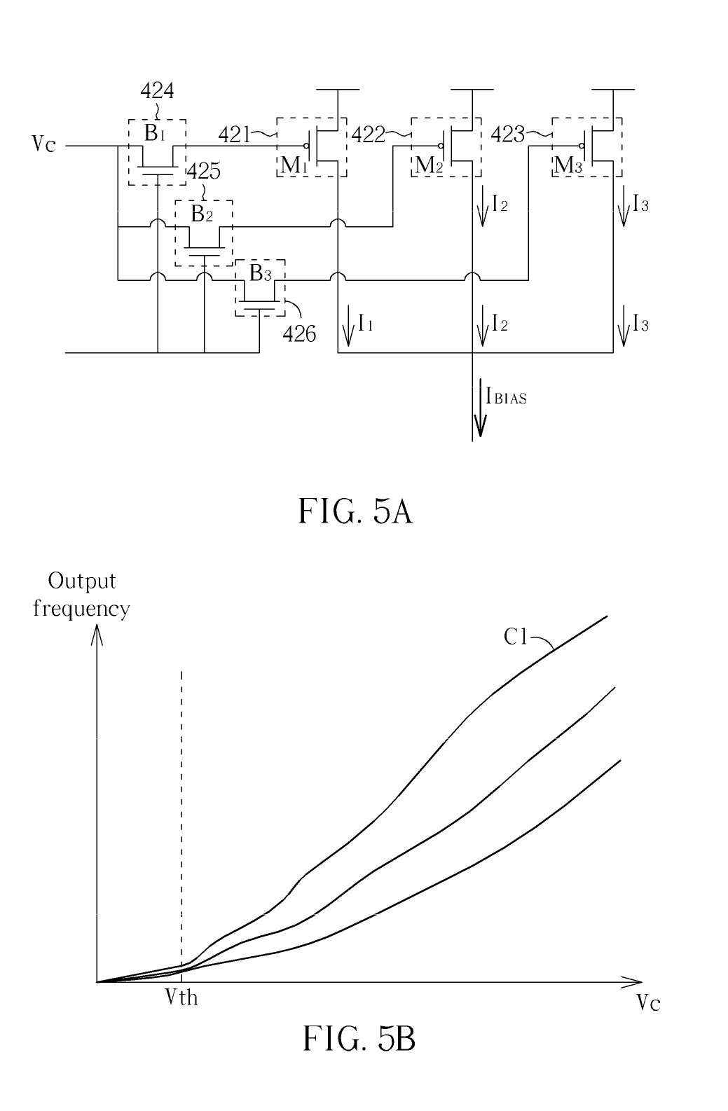

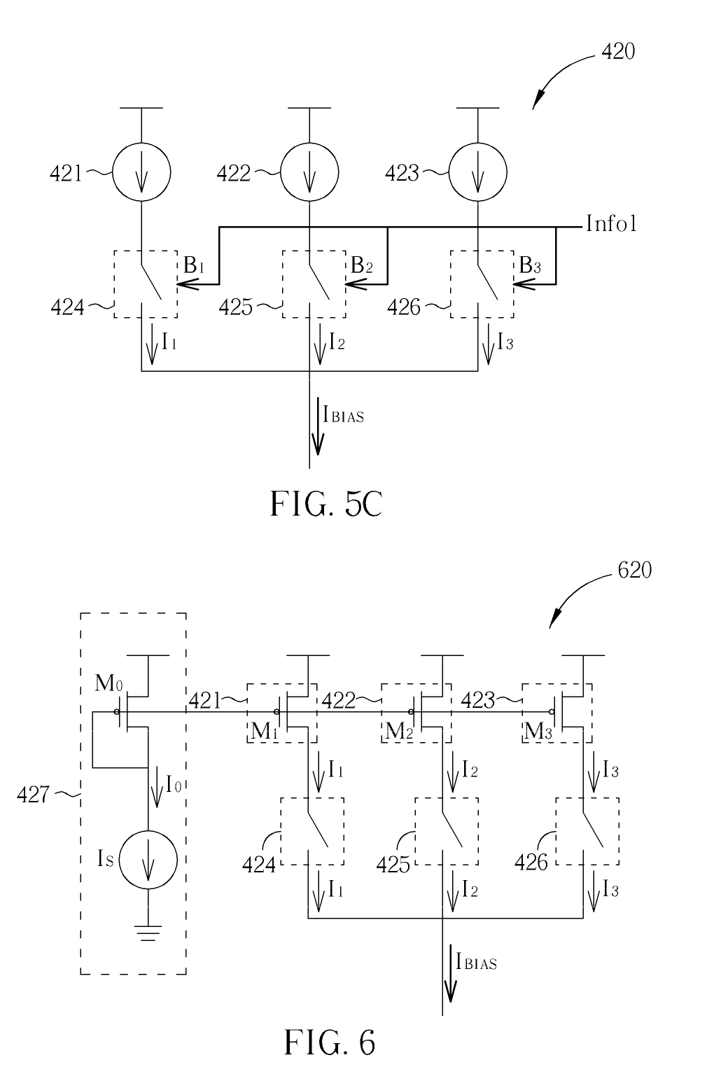

Please refer to FIG. 5A for a further illustration of the first adjusting circuit 420 shown in FIG. 4, FIG. 5A is a diagram of the first adjusting circuit 420 according to an embodiment of the present invention. The first adjusting circuit 420 includes bias circuits 421, 422, 423 and switch elements 424, 425, 426. The bias circuit 421, 422, 423 are for providing currents I₁, I₂, I₃, respectively, and the switch elements 424, 425, 426 are coupled to the bias circuit 421, 422, 423 in series, respectively. In this embodiment, the first control information Info1 is a binary code being a set of three bits, including B1, B2, B3, which are for controlling switching of the switch elements 424, 425, 426, respectively. Therefore, conducting the switching elements selectively can control whether a corresponding current provided by a bias circuit biases the core circuit 410 and choose a proper operational band, and thereby providing a current to bias the core circuit 410 according to a control voltage Vc, using the control voltage Vc to fine-tune the clock signal generated by the core circuit 410.

Please refer to FIG. 5B in conjunction with FIG. 4 and FIG. 5A, FIG. 5B is a diagram showing the relation between the control voltage Vc and the output frequency of the ring oscillator in FIG. 4 under different first control information INFO1. In FIG. 5A, the switch elements 424, 425 and 426 are coupled to gate terminals of the bias circuits 421, 422 and 423, when the control voltage Vc rises from zero, the bias current outputted by the first adjusting circuit will not rise linearly in response to the control voltage Vc, but will present a nonlinear variation before the control voltage reaches the threshold voltage Vth, therefore, each frequency band controlled by the first control information Info1 cannot sustain a proper and uniform distance between each other under different control voltage, as shown in FIG. 5B. Furthermore, in each frequency band, the control voltage Vc will start to rise again after reaching the threshold voltage Vth, for the structure shown in FIG. 5B, the curve with the highest slope, i.e., the curve C1 in FIG. 5B, will cover all the frequency bands, therefore, the ring oscillator 400 cannot lower the gain thereof (Kvco) when operating in the highest frequency band.

Please refer to FIG. 5C for a further illustration of an operation of the first adjusting circuit 420 in FIG. 4. FIG. 5C is a diagram of the first adjusting circuit 420 according to another embodiment of the present invention. The first adjusting circuit 420 also includes bias circuits 421, 422, 423 and switch elements 424, 425, 426. The bias circuit 421, 422, 423 are for providing currents I₁, I₂, I₃, respectively, and the switch elements 424, 425, 426 are coupled to the bias circuit 421, 422, 423 in series, respectively. In this embodiment, the first control information Info1 is a binary code being a set of three bits, including B1, B2, B3, which are for controlling switching of the switch elements 424, 425, 426, respectively. Therefore, conducting the switching elements selectively can control whether a corresponding current provided by a bias circuit biases the core circuit 410 or not. Therefore, when a bit within the first control information Info1 is set to be “1”, a corresponding switching element will be conducting and allow the current from the corresponding bias circuit to bias the core circuit 410. For example, when the bits B1, B2, B3 within the first control information Info1 are “101”, the switching element 424 and 426 will be conducting and guide currents I₁ and I₃ from the bias circuits 421 and 423 to bias the core circuit 410, respectively, and the switching element 425 will be open-circuited. As a result, the bias current I_{BIAS} flowing into the core circuit 410 will be I₁+I₃ (i.e., I_{BIAS}=I₁+I₃). Since the oscillating frequency of the clock signal generated by a ring oscillator is related to a gain of each ring stage, by adjusting the bias current I_{BIAS} of the core circuit 410 with the first adjusting circuit 420, the core circuit 410 will alter a bias current and a gain of each ring stage according to the first control information Info1, and thereby control the oscillating frequency of the generated clock signal, where the frequency of the clock signal is substantially positively proportional to the magnitude of the bias current I_{BIAS}.

The bias circuit 421, 422, 423 within the first adjusting circuit 420 can be implemented with a simple current mirror. Please refer to FIG. 6, which is a structural diagram of the first adjusting circuit 620 according to an embodiment of the present invention. As shown in FIG. 6, the bias circuit 421, 422, 423 are realized by transistors M₁, M₂, M₃, respectively, and the transistors M₁, M₂, M₃ output mirrored currents I₁, I₂, I₃ projected from a transistor M₀ in a source circuit 427. The source circuit 427 includes a current source I_{S} having a stable current I₀. Via a proper design of parameters such as length-to-width ratios among the transistors M₀, M₁, M₂, M₃, the mirror currents I₁, I₂, I₃ will present specific relation to the current I₀ of the source circuit 427. In this embodiment, the currents I₁, I₂, I₃ are arranged in a specific code style, e.g., a thermometer code style or a binary code style, and the first control information Info1 also arranges a set of binary bits (i.e., B₁, B₂, B₃) with the same specific code style to coordinate currents I₁, I₂, I₃. However, this embodiment is for illustrative purpose only, and is not supposed to be a limitation to the scope of the present invention. For example, the number of the switching elements and the bias circuits can be designed according to practical implementation requirements, and is not limited to be three; furthermore, the relation among the currents I₁, I₂, I₃ is also not limited to be arranged by the thermometer code fashion, and different ratios can be adopted according to different design considerations.

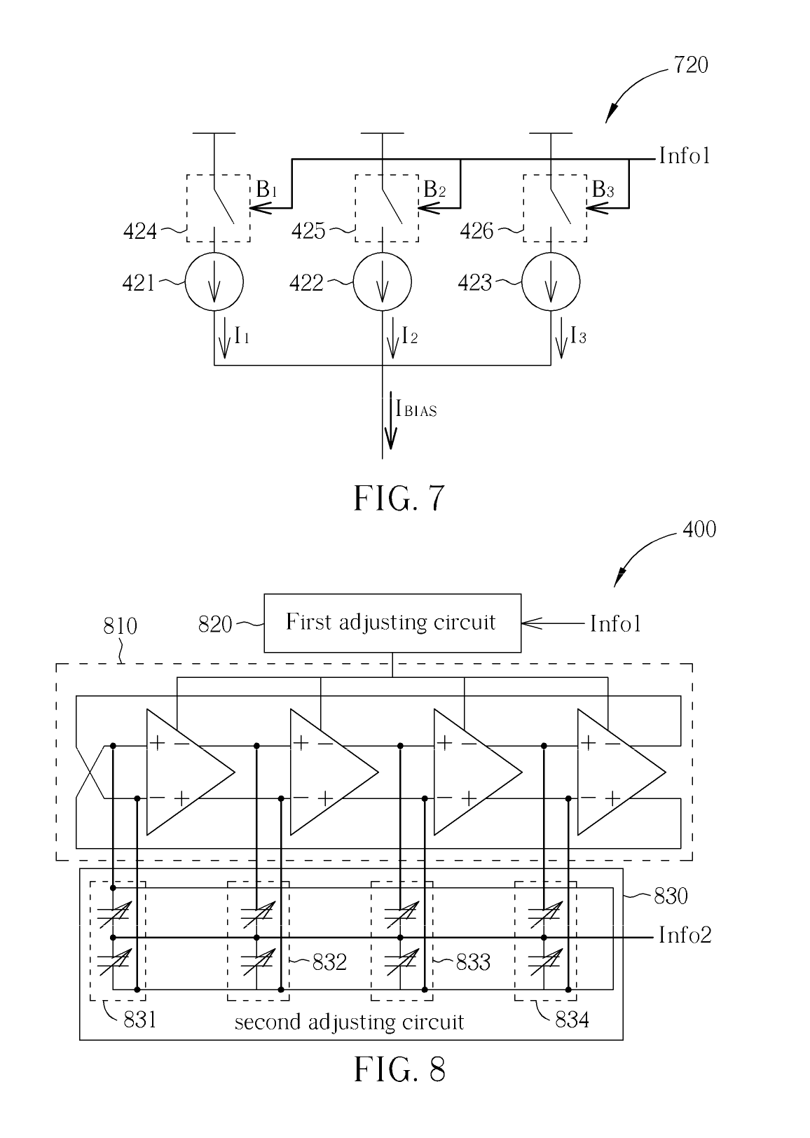

In addition, the connection structure of the switching elements and the bias circuits is also not limited to the architecture shown in FIG. 5. Please refer to FIG. 7, which is a diagram of a first adjusting circuit 720 according to another embodiment of the present invention. The first adjusting circuit 720 includes circuit elements having functions and structures substantially identical to the first adjusting circuit 420 shown in FIG. 5, and the primary difference is that the switching elements 424, 425, 426 within the first adjusting circuit 720 are coupled between the supply voltage and the bias circuits 421, 422, 423, rather than between the bias circuits 421, 422, 423 and the core circuit 410. However, the switching elements within the first adjusting circuit 720 can also control the bias circuits according to the first control information Info1, and further control a magnitude of the bias current flowing into the core circuit 410. This kind of variation in design also falls within the scope of the present invention. As those skilled in this art can readily understand the operation of the first adjusting circuit 720 after reading description directed to the first adjusting circuit 420 in FIG. 5, further description about the first adjusting circuit 720 is therefore omitted here for brevity.

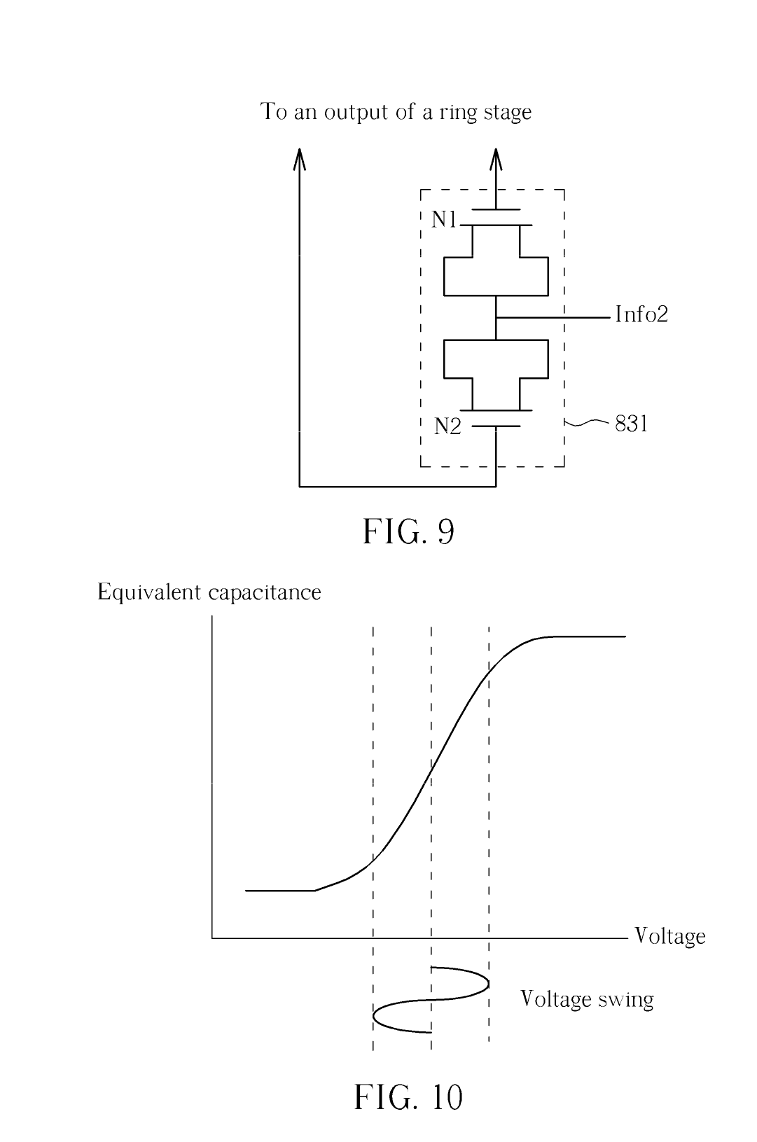

Regarding the circuit structure shown in FIG. 4, the first adjusting circuit 420 provides a mechanism of altering the gain of each ring stage in the ring oscillator 400, so as to adjust a frequency of the clock signal generated by the core circuit 410. However, the first adjusting circuit 420 only provides a mechanism of adjusting the clock signal frequency of the ring oscillator 400 non-continuously, to adjust the frequency of the clock signal more accurately, the present invention further provides another fine-tune mechanism. Please refer to FIG. 8, which is a diagram of a ring oscillator 800 according to a second embodiment of the present invention. The ring oscillator 800 includes (but not limited to) a core circuit 810 for outputting a clock signal, a first adjusting circuit 820, and a second adjusting circuit 830. The function and structure of the core circuit 810 and the first adjusting circuit 820 are substantially identical to the core circuit 410 and the first adjusting circuit 420 shown in FIG. 4, further description is omitted here for brevity. The second adjusting circuit 830 is for receiving second control information Info2 and adjusting the clock signal generated by the core circuit 810 according to the second control information Info2. Unlike the first adjusting circuit 820 implemented to adjust the bias current, the second adjusting circuit 830 is implemented to adjust a frequency of the clock signal via altering a loading at each ring stage. Please refer to FIG. 8 again. The second adjusting circuit 830 includes four adjusting elements 831, 832, 833, 834, and each adjusting element is coupled to an output terminal of a ring stage (or an input terminal of the next ring stage). In this embodiment, each adjusting element includes two variable capacitors each having one terminal coupled to an output terminal of a corresponding ring stage (or an input terminal of a next ring stage) and the other terminal coupled to the second control information Info2. Please refer to FIG. 9 for a further structural illustration of the adjusting element 831 in the second adjusting circuit 830; FIG. 9 is a diagram of the adjusting element 831 according to an embodiment of the present invention. Please note that in this embodiment, the structures of the adjusting elements 831, 832, 833, 834 are substantially the same, therefore only the adjusting element 831 is taken as an example for illustration. The adjusting element 831 includes N-channel metal oxide semiconductor (MOS) transistors N1 and N2, where the drain and the source of each of the transistors N1 and N2 are connected to each other and coupled to the second control information Info2, and the gate of each of the transistors N1 and N2 is coupled to an output terminal of a ring stage (or an input terminal of a next ring stage) in the core circuit 810. In this example, the second control information Info2 is an adjustable voltage. Thus, when the second control information Info2 varies, the size of the PN junction within the transistors N1 and N2 will also change accordingly, resulting in a different capacitance value. When a capacitance value at an output terminal of a ring stage of the core circuit 810 is changed, the loading thereof is also changed accordingly; therefore, the delay time provided by the ring stage is adjusted accordingly. With a proper design, when the first adjusting circuit 820 adjusts the core circuit 810 according to the first control information Info1, a voltage swing of the clock signal will be located totally within a linear region of the variable capacitor in the adjusting element 831; that is to say, when the clock signal varies due to oscillation, the voltage swing will not exceed the linear region of the variable capacitor to generate unwanted non-linear signal components.

Please refer to FIG. 10 in conjunction with FIG. 9; FIG. 10 is a diagram showing the relation between the voltage across a variable capacitor and the equivalent capacitance of the variable capacitor when the transistor N1 in FIG. 9 is utilized as the variable capacitor. When the clock signal oscillates, the voltage swing also varies upward and downward periodically. If the voltage swing exceeds the linear region of the variable capacitor, the equivalent capacitance within each period will be uneven, and further present non-linear signal components; therefore, with a proper design, the swing of the voltage variation can be within the linear region of the variable capacitor. In this way, the equivalent capacitance will be a stable value within each period, and a stable clock signal can be thereby derived.

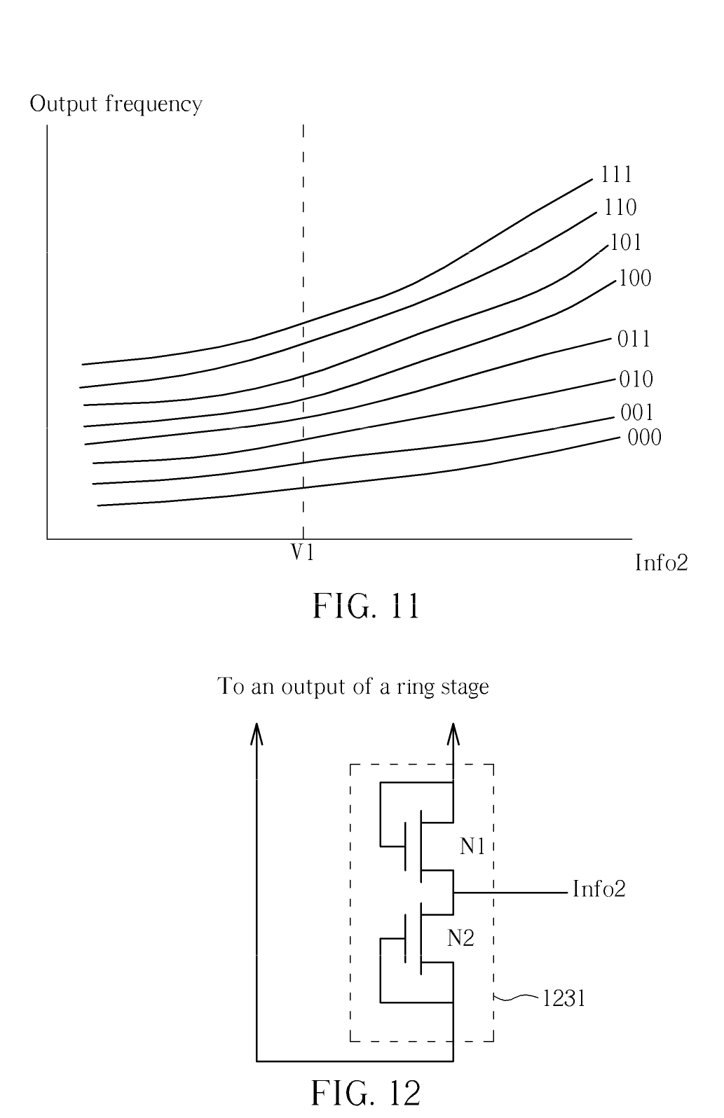

Please refer to FIG. 11, which is a diagram showing the relation between the second control information Info2 and output frequency of the ring oscillator 800 in FIG. 8 under different first control information Info1 . As shown in FIG. 11, the output frequency of the ring oscillator 800 is approximately proportional to the second control information Info2 (positively correlated) under different first control information (from “000” to “111 ”); in addition, when the second control information is fixed, the output frequency of the ring oscillator 800 is also proportional to the first control information (positively correlated). For example, when the second control information Info2 equals to a fixed voltage V1, the output frequency of the ring oscillator 800 will be approximately proportional to the first control information Info1, i.e., intervals between each neighboring curves of the different first control information Info1 will be very close to each other, revealing a great linearity of the ring oscillator 800.

Please refer to FIG. 12, which is a diagram of the adjusting element 1231 according another embodiment of the present invention. Like the adjusting element 831, the adjusting element 1231 also has two N-channel MOS transistors N1 and N2; however, the transistors N1 and N2 are diode-connected to form variable capacitors, and this kind of variation in design also falls within the scope of the present invention. In addition, other embodiments may also utilize P-channel MOS transistors to realize the variable capacitors in the adjusting element 1231, and this kind of design variation also obeys the spirit of the present invention.

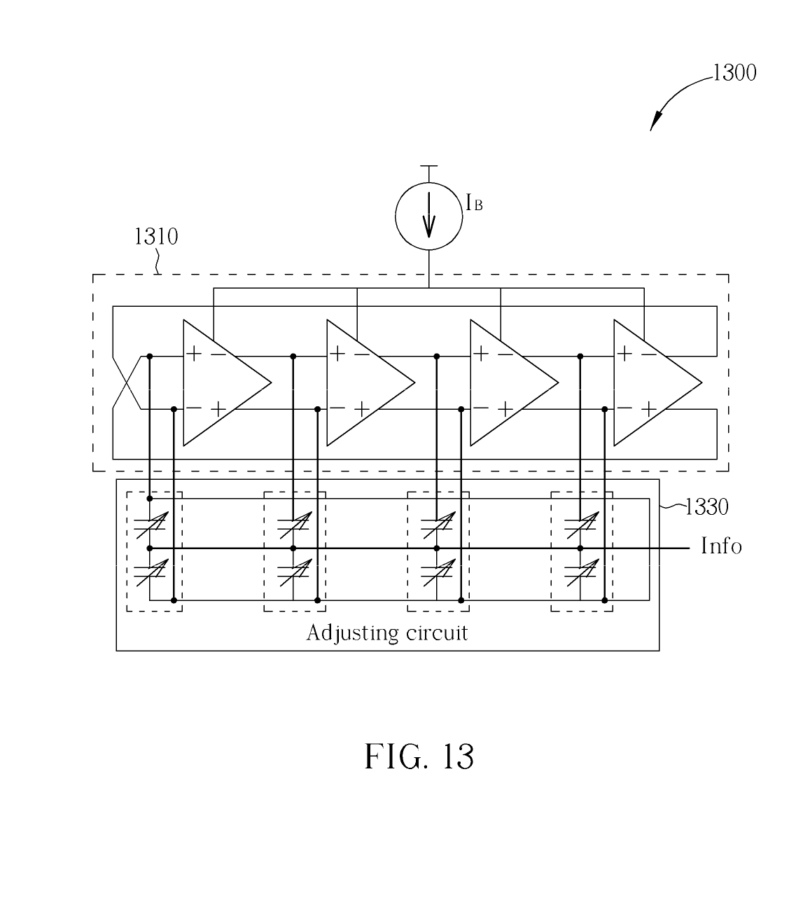

The aforementioned embodiments are for illustrative purpose only, and the adjusting circuits therewithin can be utilized independently or combined together. For example, please refer FIG. 13, which is a diagram of a ring oscillator 1300 according to a third embodiment of the present invention. The ring oscillator 1300 includes a current source I_{B}, a core circuit 1310 and an adjusting circuit 1330, wherein the current source I_{B} is for providing a constant bias current to the core circuit 1310, the function and structure of the core circuit 1310 and the adjusting circuit 1330 are substantially identical to the core circuit 810 and the second adjusting circuit 830 shown in FIG. 8, and the adjusting circuit 1330 will adjust a loading of each ring stage in the core circuit 1310 according to control information Info, thereby controlling a frequency of a clock signal generated from the ring oscillator 1300. However, for ring oscillator 1300, the adjusting circuit 1330 is utilized to continuously adjust the clock signal frequency outputted by the ring oscillator 1300, the gain (Kvco) of the ring oscillator 1300 can be sustained within a very small range, and therefore a great phase noise can be achieved, but the operational frequency coverage is also limited by the gain and the control information Info (operational frequency range =Kvco*Info), the overall performance is still not competitive to the ring oscillator 800.

To summarize, the present invention provides a ring oscillator with high linearity and adjustable frequency. Via controlling a bias current of the ring oscillator, the goal of controlling a frequency of an output signal can be achieved. In addition, the present invention simultaneously utilizes a transistor capacitor (e.g., a MOS capacitor) coupled to each ring stage to adjust a loading of each ring stage. In this way, the frequency of the output signal can be further fine-tuned. Besides, with a proper design, the ring oscillator of the present invention can have a wide adjustable frequency range while preserving great linearity.

Those skilled in the art will readily observe that numerous modifications and alterations of the device and method may be made while retaining the teachings of the invention.

What is claimed is:

1. A ring oscillator, comprising:
a core circuit, for outputting a clock signal, comprising:
a plurality of ring stages;
wherein each ring stage comprises an output node and an input node, the output node of the ring stage is coupled to an input node of a next ring stage, and the input node of the ring stage is coupled to an output node of a previous ring stage; and
a first adjusting circuit, coupled to the core circuit, for receiving a plurality of first control information and referring to the plurality of first control information to adjust the clock signal generated by the core circuit non-continuously, the first adjusting circuit comprising:
a plurality of bias circuits, for providing a plurality of currents, respectively; and
a plurality of switch elements, coupled to the bias circuits in series and receives the plurality of first control information, respectively;
wherein each switch element is selectively conducting according to a corresponding first control information for determining whether a current provided by a corresponding bias circuit is utilized to bias the core circuit;
a second adjusting circuit, coupled to the core circuit, for receiving a second control information and adjusting the frequency of the clock signal according to the second control information, the second adjusting circuit comprising:
at least one adjusting element, couple between an input node of a first ring stage and an output node of a second ring stage, wherein the first ring stage and the second ring stage are neighboring to each other within the ring stages, the adjusting element comprises at least one variable capacitor, and the variable capacitor is a transistor having two terminals thereof connected to each other.

2. The ring oscillator of claim 1, wherein the first adjusting circuit adjusts a bias current of the core circuit according to the first information, and a frequency of the clock signal generated from the core circuit is substantially positively proportional to the bias current.

3. The ring oscillator of claim 1, wherein the currents provided by the bias circuits are mirrored currents projected from a source circuit.

4. The ring oscillator of claim 1, wherein the currents provided by the bias circuits are distributed with a thermometer code style or a binary code style.

5. The ring oscillator of claim 4, wherein the first control information includes binary bits utilized for controlling the currents distributed with the thermometer code style or a binary code style.

6. The ring oscillator of claim 1, wherein when the first adjusting circuit adjusts the core circuit according to the first control information, a voltage swing of the clock is totally within a linear region of the variable capacitor.

7. A ring oscillator, comprising:
a core circuit, for outputting a clock signal, comprising:
a plurality of ring stages;
wherein each ring stage comprises an output node and an input node, the output node of the ring stage is coupled to an input node of a next ring stage, and the input node of the ring stage is coupled to an output node of a previous ring stage; and
a first adjusting circuit, coupled to the core circuit, for receiving a plurality of first control information and referring to the plurality of first control information to adjust a gain of each ring stage within the core circuit non-continuously, the first adjusting circuit comprising:
a plurality of bias circuits, for providing a plurality of currents, respectively; and
a plurality of switch elements, coupled to the bias circuits in series and receives the plurality of first control information, respectively;
wherein each switch element is selectively conducting according to a corresponding first control information for determining whether a current provided by a corresponding bias circuit is utilized to bias the core circuit;
a second adjusting circuit, coupled to the core circuit, for receiving a second control information and adjusting a loading of each ring stage within the core circuit according to the second control information, the second adjusting circuit comprising:
at least one adjusting element, couple between an input node of a first ring stage and an output node of a second ring stage, wherein the first ring stage and the second ring stage are neighboring to each other within the ring stages, the adjusting element comprises at least one variable capacitor, and the variable capacitor is a transistor having two terminals thereof connected to each other.

8. The ring oscillator of claim 7, wherein the first adjusting circuit adjusts a bias current of the core circuit according to the first information, and a frequency of the clock signal generated from the core circuit is substantially positively proportional to the bias current.

9. The ring oscillator of claim 7, wherein the currents provided by the bias circuits are mirrored currents projected from a source circuit.

10. The ring oscillator of claim 7, wherein the currents provided by the bias circuits are distributed with a thermometer code style or a binary code style.

11. The ring oscillator of claim 10, wherein the first control information includes binary bits utilized for controlling the currents distributed with the thermometer code style or a binary code style.

12. The ring oscillator of claim 7, wherein when the first adjusting circuit adjusts the core circuit according to the first control information, a voltage swing of the clock is totally within a linear region of the variable capacitor.

13. A control method of a ring oscillator, comprising:
utilizing at least one switch element to control a bias current of the ring oscillator according to a first control information to non-continuously adjust a frequency of a clock signal of the ring oscillator; and
utilizing a variable capacitor coupled to at least one ring stage within the ring oscillator to adjust a loading of the at lease one ring stage to continuously adjust the frequency of the clock signal.

14. The control method of claim 13, wherein the bias current of the core circuit and the frequency of the clock signal generated from the ring oscillator is substantially positively proportional to the bias current.

15. The control method of claim 13, wherein the bias current is a mirrored current projected from a source circuit.

16. The ring oscillator of claim 13, wherein the bias current is distributed with a thermometer code style or a binary code style.

17. The ring oscillator of claim 16, wherein the first control information includes binary bits utilized for controlling the currents distributed with the thermometer code style or a binary code style.

18. The ring oscillator of claim 13, wherein when adjusting the ring oscillator according to the first control information, a voltage swing of the clock signal is totally within a linear region of the variable capacitor.
